(19) United States
(12) Patent Application Publication
(10) Pub. No.: US 2026/0164557 A1
(43) Pub. Date: Jun. 11, 2026

(54) M.2 DOCKING DEVICE

(71) Applicant: HEWLETT PACKARD ENTERPRISE DEVELOPMENT LP, Spring, TX (US)

(72) Inventors: Chih-Wei Chiang, Taoyuan City (TW); Peng Chianghsieh, Taoyuan City (TW); Kuan-Wei Chen, Taipei City (TW)

(21) Appl. No.: 18/975,231

(22) Filed: Dec. 10, 2024

(51) Int. Cl. H05K 1/18

(52) U.S. Cl. CPC H05K 1/18; H05K 2201/10159; H05K 2201/1031

(57) ABSTRACT

A docking device, a system and a method. The device comprising a bracket assembly, a pivoting retainer pivotally attached to the bracket assembly and a translating holder located within the bracket assembly, wherein the pivoting retainer is configured pivotally move between a latched state and an unlatched state and the translating holder is configured to translate between a first and a second position, wherein the translating holder provide structural support to M.2 modules in the first position.

### INTRODUCTION

Many information processing devices, such as servers, are configured to receive M.2 modules, such as M.2 solid state drives (SSD). Usually, those information processing devices receive the M.2 modules through M.2 sockets mounted directly to a primary system board of the device or through M.2 sockets mounted to an expansion PCA, which is in turn connected to the primary board, e.g., via another socket such as PCI/PCIe sockets.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIG. 1 is a block diagram illustrating an example of an M.2 docking device.

FIG. 2 is a block diagram illustrating an example assembly of an M.2 docking device installed in an example information processing device, where the assembly includes M.2 modules in a connected state.

FIG. 3 is a perspective view of an M.2 docking device installed in an information processing device, where the docking device is removably attached to a board attachment plate.

FIG. 4 is a perspective view of the assembly of FIG. 3 with M.2 22110 form factor M.2 pluggable modules installed.

FIG. 5 is a perspective view of the assembly of FIG. 3 with M.2 2280 form factor M.2 pluggable modules installed.

FIG. 6A is a perspective view of the docking device of FIG. 3 in an unlatched state showing an M.2 pluggable module connected to a lower connecting area of a PCA engaging with a translating holder and one engagement of a pivoting retainer.

FIG. 6B is a perspective view of the docking device of FIG. 3 in a latched state showing the M.2 pluggable module of FIG. 6A engaged with the translating holder and the one engagement of the pivoting retainer.

FIG. 7A is a perspective view of the docking device of FIG. 3 in an unlatched state showing an M.2 pluggable module connected to an upper connecting area of a PCA engaging with two engagements of a pivoting retainer.

FIG. 7B is a perspective view of the docking device of FIG. 3 in a latched state showing an M.2 pluggable module engaged with the two engagements of the pivoting retainer.

The drawings are included to provide a further understanding of the present disclosure and are incorporated in and constitute a part of this specification. The drawings illustrate one or more examples of the present teachings and together with the description explain certain principles and operations. In some occasions, details that are not necessary for an understanding of an instance of this disclosure or that render other details difficult to perceive may have been omitted.

### DETAILED DESCRIPTION

Some information processing systems include M.2 sockets that are permanently attached to the processing device, such as by being directly mounted and soldered to the system board. The number of M.2 modules that can be used with those devices often are limited by the total M.2 sockets that come with those devices. Other information processing devices may lack M.2 sockets entirely, in which case it might not be possible to use M.2 modules. A further issue is that M.2 modules are often deployed in highly space constrained environments which can lead to difficulty of installation, such as, for example, requiring the tilting of an M.2 module to insert into the M.2 socket. In configurations where space is limited, this installation may further require taking other components apart in order to insert the M.2 modules.

One solution to some of these issues is the use of an expansion printed circuit assembly (PCA) that includes one or more M.2 sockets. The use of the PCA allows for adding multiple M.2 sockets to the device without being limited to the sockets pre-installed in the device. However, such expansion PCAs also have some challenges. One challenge is that the M.2 modules need to be physically supported once mated with the M.2 sockets of the expansion PCA, but depending on the form factor of the PCA, existing M.2 standoffs might not be suitable for this task, particularly if the PCA has vertically stacked M.2 sockets. Furthermore, in some cases the supporting structures may block insertion of the M.2 module into the M.2 socket via translation purely along the insertion axis, and instead the M.2 module may have to be tilted at an angle initially to avoid the support structure and then proceed into the M.2 socket through an insertion motion which combines pivoting and translation simultaneously. This tilting insertion procedure can be difficult to perform and increases the risk of damage to the M.2 module and/or the M.2 socket. One way to avoid the need for the tilting is to use a drive cage system into which the M.2 modules can be slidably inserted. However, such a drive cage system often requires the use of drive carries for each M.2 module, which adds costs. These costs may be financial costs of the drive cage and drive carriers and the costs to the operation of the device, such as the need to offset the added heat due to the restriction of airflow created by the drive cage. In addition, the drive cage system may require a range of open space in front of the drive cage to allow for insertion/removal of the M.2 modules, and many systems do not have sufficient free space to allow for this.

To address the above-mentioned challenges, the disclosure provides examples of M.2 docking assemblies that enable the use of an expansion PCA while providing physical support for the M.2 modules without the need for a drive cage. The M.2 docking assemblies includes attachment features that secure the M.2 modules to the expansion PCA while allowing for fast installation and removal of the M.2 modules. In particular, in some examples, the attachment features are configured to allow for insertion/removal of the M.2 modules into M.2 sockets by translation along the insertion axis without the need for the tilting insertion sequence described above. The attachment features are movable between positions in which they engage the M.2 modules and positions in which they are more distant from the M.2 modules so as to provide space for insertion/removal.

In some examples, the attachment features may include a pivoting retainer and a translating holder. The pivoting retainer may engage an end of one or more of the M.2 modules to resist translation of the M.2 module(s) out of their M.2 socket(s). In some cases, these attachment features may include springs to help keep the M.2 modules in an installed position. The M.2 docking assemblies may also include a holder feature which may contact an underside of one or more of the M.2 modules to vertically support the M.2 modules so as to prevent strain on the connector of the M.2 modules.

To install the M.2 module, in accordance with the disclosure, the attachment features (retainer(s) and/or holder) may be moved to allow room for the M.2 module to be disposed adjacent the M.2 socket (without the need for tilting, in some examples), and then the M.2 may be translated into connection with the M.2 socket. Once the M.2 module is connected to the PCA, the attachment features may be moved back to their engaged positions to hold the M.2 module in the installed position. In some cases, the attachment features that include springs may be moved to a position to hold the M.2 module by the release of a lever, which causes the spring to move the attachment feature toward the M.2 module. To remove the M.2 module, pressure can be applied to the lever of the attachment feature to move it away from the M.2 module, allowing for its removal from the PCA.

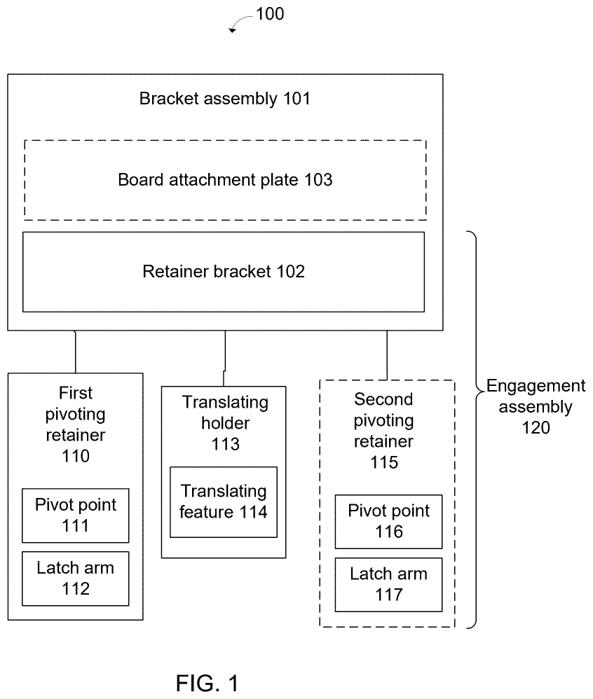

These and other examples will be described in greater detail below in relation to FIGS. 1-7.

Now referring to FIG. 1, a docking device 100 is presented. Docking device 100 is a device configured to be installed in an information processing system, such as a server, networking device, or other information processing system. In particular, docking device 100 is configured to hold M.2 pluggable modules in a connected state with a printed circuit assembly electrically attached to a primary system board. The docking device 100 is also configured to allow for installation and removal of the M.2 pluggable modules without requiring disassembly of any components.

Docking device 100 includes a bracket assembly 101, a first pivoting retainer 110 and a translating holder 113. In some instances, docking device 100 may include a second pivoting retainer 115.

The bracket assembly 101 is configured to mount the docking device 100 to the information processing system, such as by mounting to the system board, and supports the other parts of the device 100. Bracket assembly 101 includes a retainer bracket 102 which supports first pivoting retainer 110 and second pivoting retainer 115 (if present). The retainer bracket 102, first pivoting retainer 110 and translating holder 113 may be collectively referred to as engagement assembly 120 for ease of description. In examples in which docking device 100 includes a second pivoting retainer 115, the second pivoting retainer 115 may also be referred to as part of engagement assembly 120.

In some instances, bracket assembly 101 may include a board attachment plate 103 which is mountable to the system board or other support structure, with the retainer bracket 102 being attached to the board attachment plate 103. Retainer bracket 102 may removably attach to board attachment plate 103. In some examples, board attachment plate 103 includes multiple sets of attachment features arranged at different locations so as to allow retainer bracket 102 to be attached to the board attachment plate 103 at different positions. This can enable the docking device 100 to be used with different sizes of M.2 modules, such as shorter form factor M.2 modules, such as a M.2 2280, or longer form factor M.2 modules, such as a M.2 22110. In other examples, board attachment plate 103 is omitted and retainer bracket 102 is mountable directly to the system board or other support structure of the information processing device.

The first pivoting retainer 110 is attached to the retainer bracket 102. In a configuration where board attachment plate 103 is used, first pivoting retainer 110 is also configured to attach to the board attachment plate 103. First pivoting retainer 110 is configured to attach to retainer bracket 102 and board attachment plate 103 at a pivoting point 111. As used herein, the pivoting point 111 is an attachment feature that enables first pivoting retainer 110 to pivotally rotate around its axis when first pivoting retainer 110 is attached to the retainer bracket 102, and board attachment plate 103, if it is being used. For example, the pivoting point 111 may be a pivot joint fastener, or rotational fastener, that secures the first pivoting retainer 110 to an aperture of the retainer bracket 102 while enabling pivoting rotation of the first pivoting retainer 110. Examples may include hinge mechanisms, pivot screws, snap-in pivot pins, and the like. The first pivoting retainer 110 also includes a latch arm 112 that is configured to hold an M.2 pluggable module in an installed position. Latch arm 112 may include a protrusion configured to partially fit a notch of an M.2 component. The protrusion of the latch arm 112 may be used to prevent movement of the M.2 components when engaged by the latch arm 112.

The translating holder 113 is located within retainer bracket 102. In configurations where board attachment plate 103 is used, translating holder 113 is configured to removably attach to the board attachment plate 103. Translating holder 113 includes an attachment feature for removably attaching to attachment plate 103. For example, board attachment plate 103 may include one or more apertures shaped as to enable translation motion of translating holder 113 when attached to the board attachment plate 103. In an example, translating holder 113 may move in a rectilinear motion between a first position, which allows insertion of an M.2 module, and a second position, which assists in holding the M.2 module in an installed position. Examples of the attachment may include flexures, sliding clips or brackets, sliding joints, slot-and-pin mechanisms, and the like.

Translating holder 113 includes a translating feature 114 used for moving the translation holder 113 between the first and second positions. Translating feature 114 may be a handle, or a protrusion from the main body of the translating holder 113, that enables a user to move the translating holder 113 between the first and second positions. In an example, board attachment plate 103 may also include position holders for maintaining then translation holder 113 in a first or second position. In some instances, translating feature 114 may include a protrusion configured to mate with the position holders. It should be noted that the movement of the translating feature causes the protrusion to decouple from the position holder that it is mated with.

The second pivoting retainer 115 includes pivoting point 116 and latch arm 117. Pivoting point 116 and latch arm 117 are the same as pivot point 111 and latch arm 112, respectively. In instances, docking device 100 may include second pivoting retainer 115 when the desired capacity, or capacity of the PCA being used, for M.2 modules is beyond the capacity of the first pivoting retainer 110. For example, in a configuration where each of the first and second pivoting retainers 110/115 engages with two M.2 modules, the use of both retainers enables four M.2 modules to be held in a connected position. In instances, first pivoting retainer 110 and/or second pivoting retainer 115 include a spring. For example, first and second pivoting retainers 110/115 may hold M.2 modules in an installed position using the force towards the M.2 modules provided by the springs, this maintaining first and second pivoting retainers 110/115 in a latched state when no force is applied against the spring. In instances, the spring may be a torsion spring. Spring may be other types of springs such as, plastic cantilever beams, coil springs, wave springs, and the like.

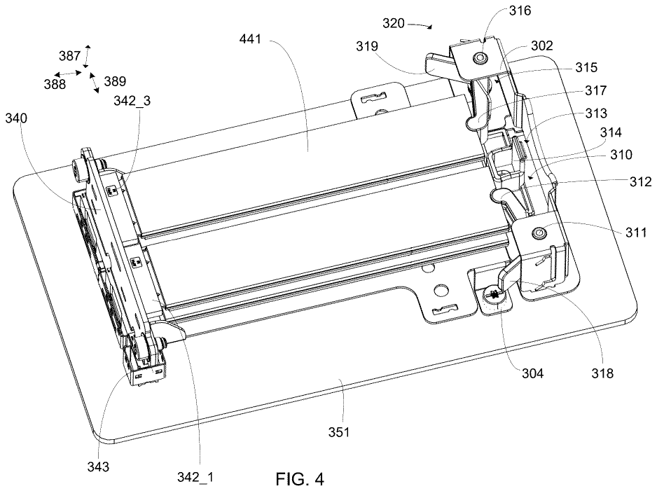

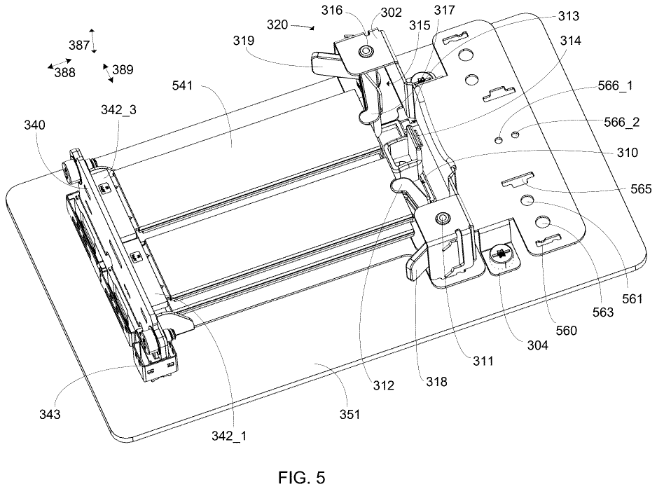

In instances, board attachment plate 103 includes a first set of apertures used for removably attaching engagement assembly 120 in a first configuration, and a second set of apertures used for removably attaching engagement assembly 120 in a second configuration. For example, engagement assembly 120 may be configured to engage with a long form factor M.2 module, such as M.2 22100, in a first configuration, while engagement assembly 120 may be configured to engage with a short form factor M.2 module, such as M.2 2280, in a second configuration. Examples of each configuration are provided in reference to FIGS. 4 and 5.

In both sets of apertures, board attachment plate 103 may include fastening apertures, used for securing retainer bracket 102 to the plate. Fastening apertures may include apertures configured to receive fasteners, such as screws, or other attachment features, such as plastic snap-on clips, and the like.

Board attachment plate 103, in both sets of apertures, may include a pivot aperture. Pivot aperture may include any type of aperture that enables a pivoting rotation of the attached component. For example, first pivoting retainer 110 may be secured to the board attachment plate 103 at the pivot point 111. It should be noted that first pivoting retainer 110 and/or second pivoting retainer 115 may be secured to the board attachment plate 103 based on the other end of the pivot point 111/116 being secured to retainer bracket 102. In other words, first and/or second pivoting retainers 110/115 are secured in place by the retainer bracket 102 being attached to the board attachment plate 103. In instances, where board attachment plate 103 is not used, the pivot points 111/116 may be secured directly to an aperture in a system board. It should be noted that, although not required to be used, board attachment plate 103 provides modularity of use by only requiring one or two attachment points in the primary board, making it easier to be installed in many systems, while also providing flexibility of use by enabling two configurations (i.e. two types of M.2 modules) to be used.

Board attachment plate 103, in both sets of apertures, also may include a translation aperture. Translating aperture may include any type of aperture that enables a translation motion of the attached components. In instances, translation holder 113 may be removably attached to board attachment plate 103 at the translation aperture. For example, translating holder 113 may include a plastic protrusion configured to fit within translation aperture and move between a first position and a second position. The plastic protrusion may include a triangular shaped tip that holds the translating holder 113 attached to board attachment plate. For example, a user may provide force to the protrusion as to bend the protrusion. In a bent state, the protrusion is inserted in the translation aperture. The protrusion tip may be shaped in a manner that it does not pass through the translation aperture in a non-bent state, thus enabling the translating motion of translating holder 113 while maintaining the attachment.

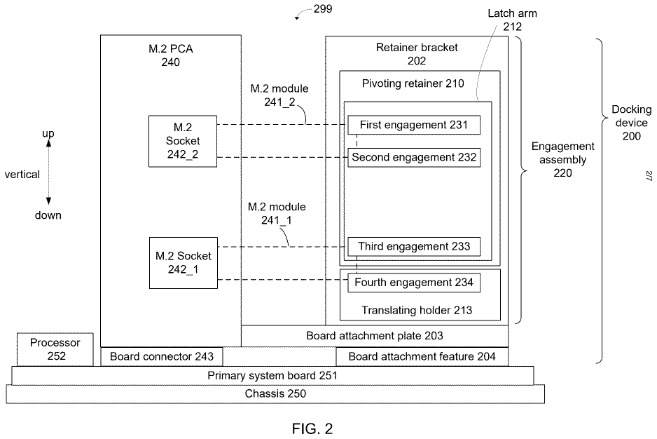

Now referring to FIG. 2, an example system 299 is shown. System 299 is an information processing system, such as a server, networking device, or other information processing system. System 299 includes a chassis 250, a primary system board 251 supported by the chassis 250, an M.2 PCA 240, a docking device 200 and M.2 modules 241_1/241_2 removably installable in system 299. System 299 also includes at least a processor 252 communicatively connected to the primary system board 251.

A “chassis,” as used herein, is a support structure, such as an enclosure or tray, designed to support, and in some cases house, hardware components, such as primary system board 251. In instances, chassis 250 may house primary system board 251. In instances, primary system board 251 may be attached to a section of chassis 250. A “system board,” as used in this disclosure, is a central circuit board comprising a central processing unit (CPU) and supporting circuitry, and configured to enable connection and integration among a plurality of components and devices. As noted above, processor 252 is communicatively connected to primary system board 251. As used herein, a “processor” is a component configured for executing instructions, performing calculations and managing tasks. In instances, system 299 may include two or more processors 252 mounted to primary system board 251. In an example, without limitations, processor 252 may be a Central Processing Unit, (CPU).

The example M.2 PCA 240 includes M.2 socket 242_1 and M.2 socket 242_2. M.2 sockets 242_1/242_2 are configured to receive M.2 connectors of M.2 modules 241_1/241_2. M.2 sockets 242_1/242_2 may include any type of M.2 key configuration. For example, M.2 sockets 242_1/242_2 may be of B-key type, M-key type and/or B+M-key type. M.2 connectors of M.2 modules 241_1/241_2 may be configured to mate with the key types of M.2 sockets 242_1/242_2. It should be noted that system 299 is described with M.2 module 241_1 and M.2 module 241_2, and M.2 PCA 240 with M.2 socket 242_1 and M.2 socket 242_2 for ease of description. It should be noted that system 299 may include additional M.2 sockets and M.2 modules not described herein. In some examples, M.2 sockets 242_1 and 242_2 are arranged in a vertically stacked arrangement, with one being positioned vertically above the other. Vertical, as used herein, refers to a direction perpendicular to system board 251, as shown in FIG. 2. This term is not intended to limit the orientation of the system relative to an external reference frame, such as the ground (e.g., “vertical” as used herein can be oriented parallel to the ground it the system is so oriented).

M.2 PCA 240 is communicatively attached to primary system board 251 through board connector 243. Board connector 243 may be a standard riser card connector, such as PCI/PCI express (PCIe) connector. M.2 PCA 240 may be attached to board attachment plate 203, which will be described below. For example, M.2 PCA 240 may be attached to board attachment plate 203 using fasteners, or other attachment features. In instances, board attachment feature 204 is shaped as to maintain retainer bracket 202 at the same level as PCA 240 such that M.2 modules 241_1/242_2 are levelled and parallel to primary system board 251.

The M.2 modules 241_1/242_2 includes an end with M.2 connectors, configured to connect to M.2 sockets 242_1/242_2, and an opposing end that includes a notch.

Docking device 200 includes a board attachment plate 203. Board attachment plate 203 attaches the docking device 200 to the board 251. In some example, plate 203 includes a board attachment feature 204. Board attachment plate 203 is configured to be attached to the primary system board 251 using board attachment feature 204. In instances, board attachment feature 204 elevates board attachment plate 203 as to provide a space between the primary system board 251 and the board attachment plate 203.

Docking device 200 further includes an engagement assembly 220, which includes retainer bracket 202, a pivoting retainer 210 and a translating holder 213. Docking device 200 may be an example implementation of, or include, docking device 100. Retainer bracket 202 and translating holder 213 are configured to removably attach to board attachment plate 203. For example, retainer bracket 202 may be fastened to attachment plate 203. Translating holder 213, in an example, may be removably attached to a translation aperture of the attachment plate 203. Docking device 200 may be an implementation example of, or include, docking device 100. Elements in FIG. 2 whose reference numbers have the same last two digits as elements described above in reference to FIG. 1, such as 120 and 220, correspond to one another, meaning the element in FIG. 2 is the same as, or an implementation example of, the corresponding element in FIG. 1.

Pivoting retainer 210 is configured to pivotally attach to retainer bracket 202 and to board attachment plate 203. For example, board attachment plate 203 and retainer bracket 202 may include apertures configured to receive an attachment by pivoting retainer 210, such as through rotational fasteners. Pivoting retainer 210 may pivotally attach to retainer bracket 210 at one end and pivotally attach to board attachment plate 203 at the other end. Translating holder 213 is configured to removably attach to board attachment plate 203 in a configuration that enables translation motion of the translation holder 213.

Pivoting retainer 210 includes a latch arm 212, where the latch arm 212 includes a first engagement 231, a second engagement 232 and a third engagement 233. In this example, first and second engagements 231/232 are configured to engage with M.2 module 241_2 to hold the M.2 module 241_2 in an installed position. In instances, first and second engagements 231/232 may be edges protruding from latch arm 212. In instances, the first and second engagements 231/232 may engage with notches of the non-connecting end of M.2 module 241_2. For example, first engagement 231 may partially cover the edge of the M.2 module 241_2 that faces away from the primary system board 251, preventing movement of the M.2 module 241_2 on that direction, while second engagement 232 may partially cover the edge of the M.2 module 241_2 that faces towards the primary system board 251, preventing movement of the M.2 module 241_2 on that direction. As noted above, the first and second engagements 231/232 are configured to fit into a notch of the M.2 module 241_1, which prevents movement of the M.2 module 241_1 in directions parallel to the primary system board 251 (i.e. sideways). It should be noted that the use of first engagement 231 and second engagement 232 in the manner described is used for reducing force pressure being applied to M.2 sockets 242_1 by the M.2 module 241_2.

Translating holder 213 includes a fourth engagement 234. Fourth engagement 234 may be a protrusion form the translating holder 213 that is configured to fit into a notch of M.2 module 241_1. In instances, fourth engagement 234 and third engagement of pivoting retainer 210 are configured to engage with M.2 module 241_1 and hold the M.2 module 241_1 in an installed, or connected, position. In some instances, translating holder 213 may include a firth engagement. For example, in a configuration where a second pivoting retainer is used, the fifth engagement may engage with an M.2 module in conjunction with an engagement of the second pivoting retainer.

In an installed state of the docking device 200, the M.2 modules 241_1/241_2 mate with the M.2 sockets 242_1/242_2 of the PCA 240, and thus the M.2 modules 241_1/241_2 are communicatively connected to the primary system board 251 via the board connector 243 and M.2 sockets 242_1/242_2. Furthermore, the pivoting retainer 210 and translating holder 213 of the docking device 100 engage with the non-connecting end of the M.2 modules 241_1/241_2 to secure the M.2 modules 241_1/241_2 to the M.2 sockets 242_1/242_2 of PCA 240.

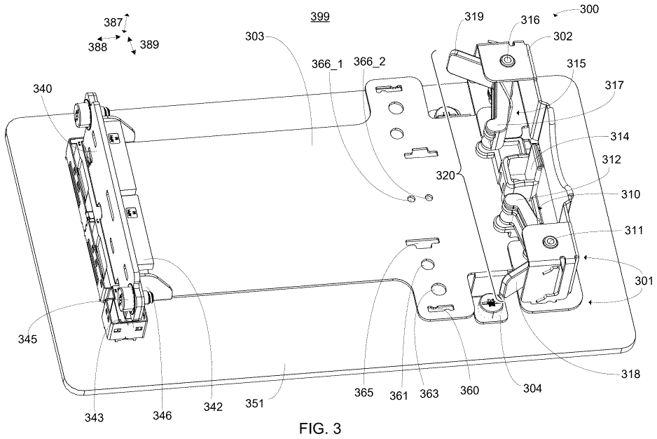

Now referring to FIG. 3-7 an example system 399 will be described. System 399 is an information processing system, such as a server, networking device, or other information processing system, and is one implementation example of system 299 described above. System 399 includes a primary system board 351 having a PCA 340 and a docking device 300 mounted thereon. The system 399 may also include a chassis and a processor, which are omitted herein for ease of description. The docking device 300 is an example implementation of docking devices 100 and 200. Docking device 300 includes a first and second pivoting retainers 310/315 and a translating holder 313. The components of system 399 are described simultaneously below for ease of understanding. However, it should be noted that docking device 300, the system board 351 and PCA 340 may be produced or sold together or separately and may be claimed separately or together herein. System 399 is an example implementation of system 299. The docking device 300 is an example implementation of docking devices 100/200. Elements in FIGS. 3-7 and elements of FIGS. 1-2 whose reference numbers have the same last two digits as elements described above in relation to FIGS. 1 and 2, such as 102 and 302, correspond to one another, with elements in FIGS. 3-7 being one implementation example of the corresponding element in FIG. 1-2.

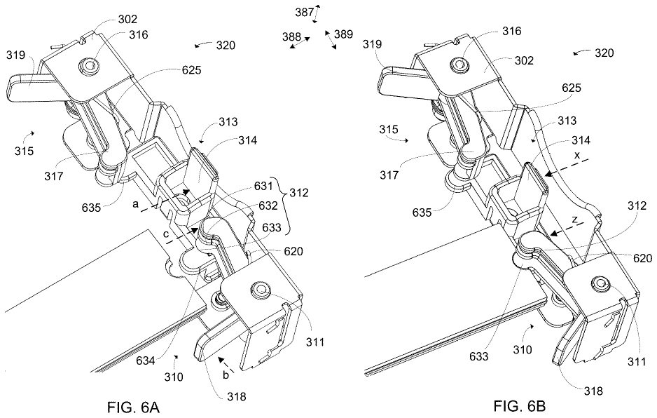

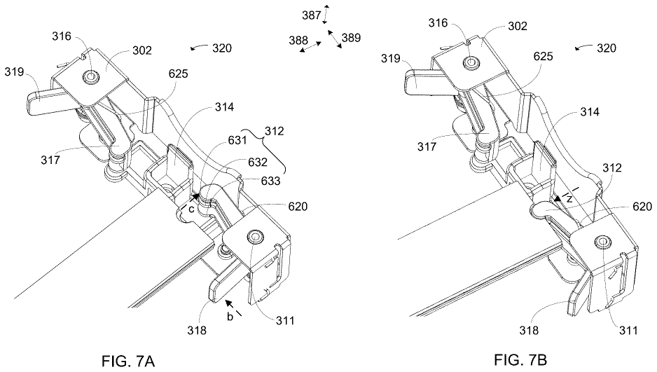

FIG. 3 shows the example system 399 without M.2 modules installed and with docking device 300 mounted in a first configuration. FIG. 4 shows the system 399 with long form factor M.2 modules 441 installed. FIG. 5 shows system 399 with docking device 300 mounted in a second configuration and short form factor M.2 modules 541 installed. FIG. 6A shows first pivoting retainer 310 in an unlatched state and translating holder 313 in a disengaged position, while FIG. 6B shows first pivoting retainer 310 in a latched state and translating holder 313 in an engaged position. FIG. 7A shows first pivoting retainer 310 in an unlatched state and FIG. 7B shows first pivoting retainer 310 in a latched state. Elements in FIG. 3-7 and elements of FIGS. 1-2 whose reference numbers have the same last two digits as elements described above in relation to FIGS. 1 and 2, such as 102 and 302, correspond to one another, with elements in FIGS. 3-7 being one implementation example of the corresponding elements in FIGS. 1-2.

Elements in reference to FIGS. 3-8 are described using vertical 387, longitudinal 388 and latitudinal 389 directions for ease of description. Vertical direction 387 is perpendicular to a face of the primary system board 330 upon which the M.2 assembly 341 is mounted. Longitudinal 388 and latitudinal 389 directions are perpendicular to each other and to the vertical direction 387 and may both also be referred to as being a “horizontal” direction on occasion. However, it should be noted that these directional descriptions are used only relative to the position of the primary system board 351. As such, for example, vertical position 387 could include a horizontal position relative to the ground, depending on the orientation of the system board 351. Motions related to the installation of M.2 modules in reference to FIGS. 6 and 7 are described using alphabetical letters. For example, one motion is described with the letters “a”, while another motion is described with a letter “b”, and so forth. The order that the motions are described, or letters used, should not be interpreted as limiting the motions to the order described, unless explicitly stated otherwise.

The example shown in FIGS. 3-5, PCA 340 includes M.2 sockets 342. M.2 sockets 342 are electrically and communicatively attached to PCA 340. In this example, PCA 340 includes M.2 sockets 342 in a stacked configuration that includes a lower connecting area and an upper connecting area.

PCA 340 also includes board connector 343. M.2 sockets 342 are communicatively and electrically connected to primary system board 351 through board connector 243. Board connector 343 may be a PCI/PCIe connector.

Docking device 300 includes a bracket assembly 301 that includes a retainer bracket 302 and a board attachment plate 303. Retainer bracket 302 removably attaches to board attachment plate 303 in a first configuration and a second configuration. FIGS. 3 and 4 shows retainer attached to board attachment plate 303 in the first configuration, while FIG. 5 show the retainer bracket 302 attached to board attachment plate 303 in the second position. As noted above, in the first configuration the docking device 300 is used for holding long form factor M.2 modules, such as M.2 22110, in installed positions and in the second position the docking device 300 is used for holding short form factor M.2 modules, such as M.2 2280, in installed positions.

Referring to FIG. 3, board attachment plate includes retainer slotted apertures 360 and retainer fastened apertures 361, used for attaching retainer bracket 302 to board attachment plate 303 in a second configuration. As used herein, the retainer slotted apertures 360 are slots for receiving a protrusion of the retainer bracket 302 of the same shape. In an example, retainer slotted apertures 360 are used for providing structural support and preventing movement of retainer bracket 302 when pivoting retainers 310/315 and translating feature 314 are interacted with. The retainer fastened apertures 361 are apertures configured to receive a fastener, such as a screw, for securing the retainer bracket 302 to the board attachment plate 303.

In instances, continuing to refer to FIG. 3, the board attachment plate 303 includes pivot apertures 363, translating apertures 365 and position holders 366_1 and 366_2, for securing pivoting retainers 310/315 and translating holder 313 in a second configuration. As used herein, the pivot apertures 363 are apertures configured to mate with the end of pivot point opposite from the end coupled to retainer bracket 302 and is configured to provide structural support of the pivoting retainers 310/315 while enabling the pivoting movement. The translation apertures 365 are apertures that enable the translating movement while securing the translating holder to the board attachment plate 303. The position holders 366_1 and 366_2 are apertures configured to maintain, respectively, the translating holder 313 in a first and second positions. As noted above, the movement of translating feature 314 will cause the translating holder 313 to decouple from position holders 366_1 or 366_2. For example, translation apertures 365 include a wider opening for inserting and removing translating holder 313, when the translating holder 313 is in a first or second position, the mating section of translating holder 313 is positioned on narrower ends of the translation apertures 365, thus staying secured to the board attachment plate 303. In an example, to remove the translating holder 313 from board attachment plate, the translating feature 314 must be positioned between position holders 366_1 and 366_2.

Now referring to FIG. 5, board attachment plate 303 also includes retainer slotted apertures 560, retainer fastened apertures 561, pivot apertures 563, translating apertures 565 and position holders 566_1/566_2 for securing engagement assembly 320 in a first configuration. The components above have the same features as the respective components in FIG. 3 and are used in the same manner in the first configuration as the components in FIG. 3 are used in a second configuration.

Board attachment plate 303 is attached to primary system board 351 using board attachment feature 304. Board attachment plate 303 is also attached to PCA 340 via a PCA attachment feature 345. PCA attachment feature 345 is attachment to board attachment plate 303 via PCA attachment sections 346. PCA attachment sections 346 are elevated sections of the board attachment plate 303 that includes apertures for receiving PCA attachment feature 345. In an example, the PCA attachment sections 346 are elevated as to maintain the board attachment plate 303 leveled with the PCA 340 to secure a component to M.2 socket 342 leveled with pivoting retainers 310/315 and translating holder 313. In instances, Board attachment feature 304 and PCA attachment feature 345 may include fasteners, such as screws, or other types of attachment features, such as retention clips, rivets, and the like.

As shown in FIGS. 6A-B and 7A-B, first pivoting retainer 310 includes a spring 620, and second pivoting retainer 315 includes a spring 625. Springs 620/625 hold first and second pivoting retainers 310/315 in a latched state. Referring to FIG. 6A, first pivoting retainer includes a first engagement 631, a second engagement 632 and a third engagement 633. Translating holder 313 includes a fourth engagement 634. First engagement 631, second engagement 632, third engagement 633 and fourth engagement 634 may be the same as, or include, first engagement 231, second engagement 232, third engagement 233 and fourth engagement 234, respectively. Translating holder 313 also includes a fifth engagement 635, which is used for engaging with another M.2 module, not shown. Second pivoting retainer 315 includes the same sets of engagements as first pivoting retainer 310. For example, fourth engagement 634 and third engagement 633 engage with the M.2 module being installed in a lower connecting area of PCA 340, as shown in FIG. 6B. In instances, if another M.2 module is connected to the lower connecting area of PCA 340, then fifth engagement 634 in conjunction with a third engagement of second pivoting retainer 315 may be used to hold the M.2 module in a connected state. As shown in FIGS. 7A and 7B, first engagement 631 and second engagement 632 engage with an M.2 module connected to an upper connecting area of PCA 340 to hold the M.2 module in a connected state.

In the examples, in FIGS. 3-7, docking device 300 also includes first pivoting retainer 310, second pivoting retainer 315 and translating holder 313. First pivoting retainer includes pivot point 311, latch arm 312 and actuation lever 318. Second pivoting retainer includes pivot point 316, latch arm 317 and actuation lever 319. As it will be described in more detail further below, actuation lever 318 is used for moving first pivoting retainer 310 into an unlatched state. Similarly, actuation lever 319 is used for moving second pivoting retainer 315 into an unlatched state.

Referring to FIG. 4, four long form factor M.2 modules 441 are shown in an installed state. As it will be described in more detail in reference to FIGS. 6AB and 7AB, an M.2 module 441 that connects to an M.2 socket 342 in the lower connecting area of the PCA 340 are held in the installed state by translating holder 313 and first pivoting retainer 310 or second pivoting retainer 315. An M.2 module 441 that connects to an M.2 socket 342 in the upper connecting area of the PCA 340 is held in the installed state by first pivoting retainer 310 or second pivoting retainer 315.

Referring to FIG. 5, four short form factor M.2 modules 541 are shown in an installed state. Similarly to described in FIG. 4, an M.2 module 541 that connects to an M.2 socket 342 in the lower connecting area of the PCA 340 are held in the installed state by translating holder 313 and first pivoting retainer 310 or second pivoting retainer 315, while that connects to an M.2 socket 342 in the upper connecting area of the PCA 340 is held in the installed state by first pivoting retainer 310 or second pivoting retainer 315. As described above, retainer bracket 302 and

In instances, referring to FIG. 6A, to secure a M.2 module 441/541 being connected to the lower connecting area of PCA 340 to its respective M.2 socket 342, one step is of translating the translating holder 313 from a first position to a second position. In FIG. 6A, this movement, shown by arrow “a,” can be effectuated by pushing on translating feature 314 towards the second position. Another step is pivoting retainer 310 towards an unlatched state. In this example, pivoting retainer 310 towards an unlatched state is performed by applying force to actuation lever 318, shown by arrow “b”, which causes latch arm 312 to move in the direction of arrow “c.” Applying force to actuation lever 318 as to move first pivoting retainer 310 involves moving latch arm 312 in the direction “c” against the resistance of spring 620. As such, the force applied in direction “b” must be higher than the resistance of the spring as to cause the latch arm 312 to move into an unlatched state.

Now referring to FIG. 6B, once the M.2 module 441/541 is connected to its respective M.2 socket 342 of the lower connecting area of PCA 340, the translating holder 313 is moved back to the first position, which can be achieved by applying force to translating feature 314 in direction “x” until fourth engagement 634 is engaged with a notch of the M.2 module 441/541. Another step involves releasing the force previously applied to actuation lever 318. Once force is no longer applied, spring 620 causes latch arm 312 to move in direction “z,” until third engagement 633 is engaged with the notch of M.2 module 441/541. Securing another M.2 module to another M.2 socket 342 of the lower connecting area of PCA 340 involves similar steps performed with translating holder 313 and second pivoting retainer 315.

Now referring to FIG. 7A, in instances, to secure to secure a M.2 module 441/541 being connected to the upper connecting area of PCA 340 to its respective M.2 socket 342 involves moving first retainer into an unlatched state. Similar to the steps described in reference to FIG. 6A, the first pivoting retainer 310 is moved into an unlatched state by applying force to actuation lever 318 in direction “b” with sufficient force applied to overcome the resistance of spring 620. By applying force to actuation lever 318, above the spring's resistance, latch arm 312 moves in direction “c”.

Now referring to FIG. 7B, once M.2 module 441/541 is connected to its respective M.2 socket 342 of the upper connecting area of PCA 340, the first pivoting retainer 310 is moved into the latch position. This is achieved by releasing the force being previously applied to actuation lever 318, which causes the latch arm 312 to move in direction “z,” by the spring, until first engagement 631 and second engagement 632 are engaged with the notch of M.2 module 441/541. Securing another M.2 module to another M.2 socket 342 of the upper connecting area of PCA 340 involves similar steps performed with second pivoting retainer 315.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic” circuitry and “electrical” circuitry.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A device comprising:
a bracket assembly;
a pivoting retainer pivotally attached to the bracket assembly; and
a translating holder located within the bracket assembly,
wherein:
the pivoting retainer is configured pivotally move between a latched state and an unlatched state, and
the translating holder is configured to translate between a first and a second position, wherein the translating holder provide structural support to M.2 modules in the first position.

2. The device of claim 1, wherein the bracket assembly is configured to attach to a primary system board of an information processing device.

3. The device of claim 1, wherein the bracket assembly further comprises a board attachment plate.

4. The device of claim 3, wherein the board attachment plate comprises a board attachment feature configured to attach to primary system board.

5. The device of claim 3, wherein the retainer bracket is configured to removably attach to the board attachment plate.

6. The device of claim 5, wherein the retainer bracket is configured to attach in a first position or a second configuration.

7. The device of claim 1, further comprising a second pivoting retainer.

8. The device of claim 1, wherein the pivoting retainer comprises a spring.

9. The device of claim 8, wherein the spring is a torsion spring.

10. The device of claim 8, wherein the spring is configured to maintain the pivoting retainer in a latched state.

11. A computing system, comprising:
a chassis comprising a base;
a system board supported by the base,
an M.2 printed circuit assembly (PCA) communicatively attached to the system board, the M.2 PCA comprising a first and a second set of M.2 sockets configured to receive a plurality of M.2 pluggable modules in an installed position; and
a docking assembly comprising:
a bracket assembly attached to the system board;
a pivoting retainer pivotally attached to the bracket assembly; and
a translating holder located within the bracket assembly,
wherein:
the pivoting retainer is configured to pivotally move between a latched state and an unlatched state, and
the translating holder is configured to translate between a first and a second position, wherein the translating holder provide structural support to M.2 modules in the first position.

12. The system of claim 11, further comprising a board attachment plate attached to the system board.

13. The system of claim 12, wherein the retainer bracket is removably attached to the board attachment plate.

14. The system of claim 13, wherein the retainer bracket and the translating holder are configured to removably attach to the board attachment plate in a first or a second configuration.

15. The system of claim 14, wherein in the first configuration the docking assembly is configured to secure one or more M.2 22110 form factor M.2 pluggable modules to the M.2 PCA, and in the second configuration the docking assembly is configured to secure one or more M.2 2280 form factor M.2 pluggable modules to the M.2 PCA.

16. The system of claim 11, wherein pivoting retainer comprises a spring.

17. The system of claim 16, wherein the spring is a torsion spring.

18. A method comprising:
translating a translating holder from a first position to a second position;
pivoting a pivoting retainer from a latched state to an unlatched state;
placing an attachment end of a first M.2 pluggable module on an engagement section of the translating holder;
connecting the first M.2 pluggable module to an M.2 printed circuit assembly, wherein connecting the first M.2 pluggable module comprises moving the first M.2 pluggable module towards the M.2 printed circuit assembly (PCA) until an M.2 connector of the first M.2 pluggable module is communicatively connected to a M.2 socket of the M.2 printed circuit assembly; and
moving translating holder from the second position to the first position causing the pivoting retainer to move to the latched state.

19. The method of claim 18, wherein the pivoting the pivoting retainer comprises applying force against a spring resistance.

20. The method of claim 19, wherein causing the pivoting retainer to move to the latched state comprises releasing the force against the spring resistance.
